(19) United States
(12) Patent Application Publication
(10) Pub. No.: US 2005/0048788 A1
(43) Pub. Date: Mar. 3, 2005

(54) Methods of reducing or removing micromasking residue prior to metal etch using oxide hardmask

(76) Inventors: Woody K. Sattayapiwat Tang, Saratoga, CA (US); George A. Kovall, Campbell, CA (US); Yi Ding, Sunnyvale, CA (US)

Correspondence Address: Gideon Gimlan;MacPHERSON KWOK CHEN & HEID LLP, Suite 226, 1762 Technology Drive, San Jose, CA, 95110, US

(21) Appl. No.: 10/649,099

(22) Filed: Aug. 26, 2003

(51) Int. Cl. H01L 21/302; H01L 21/461

(52) U.S. Cl. 438/720

(57) ABSTRACT

Significant amounts of micromasking residue have been observed at the interface between a Ti-containing ARC layer and a PE-TEOS hardmask after the hardmask has been etched and prior to the use of the etched hardmask for transferring a pattern to an underlying metal layer (e.g., aluminum). The micromasking residue can interfere with proper etching of the underlying metal layer such as by creating undesirable short circuits between metal interconnect lines. Methods are disclosed for removing and/or preventing the formation of the micromasking residue. A removing method includes the use of a relatively low average-mass physical bombardment agent in combination with a small-diameter, chemically-reactive agent for dislodging micromasking nodules by weakening their base anchors and breaking them away without causing excessive damage to underlying layers. In one embodiment, the base anchors are rich in titanium content while the micromasking nodule bodies contain titanium oxide. Chlorine is included in a residue removing plasma for volatizing the titanium of the base anchors while argon is further included in the residue removing plasma for physically bombarding the upper, oxide bodies of the micromasking nodules. A method for preventing or reducing the amount of formed, micromasking residue includes interposing an oxygen-poor interfacial layer between the metal-containing ARC layer and the oxygen-containing hardmask.

### FIELD OF DISCLOSURE

The present disclosure of invention relates generally to post-lithography etching of metal where an oxide hardmask is used to help define the etch pattern which is imparted to the metal.

The disclosure relates more specifically to post-lithography aluminum etch where a TEOS hardmask is used in combination with a metallic anti-reflection coating (ARC) to help define an etching pattern that is imparted to an underlying metal stack such as an aluminum-containing stack.

### DESCRIPTION OF RELATED ART

When a relatively tall stack of metal is to be etched for the purpose of defining a metal interconnect pattern or the like, it is sometimes desirable to use an oxide-based hardmask in place of, or in addition to an organic photoresist (PR) layer for controlling the etch-based patterning of the metal stack. The hardmask is typically used when it is believed that the PR layer may not be sufficiently hardy by itself to withstand the erosive environment of a harsh and/or long metal etch process.

More specifically, when a hardmask is to be used for propagating an etch pattern to an underlying metal layer, an organic PR layer is often first provided above a blank, still-unpatterned hardmask layer. The organic PR layer is exposed to an appropriate pattern of radiation (e.g., Deep UV though a photolithography mask) and the exposed PR is then developed so as to leave behind cross-polymerized organic PR material, where the remnant PR material is appropriately patterned over the blank hardmask layer. An oxide etch process (e.g., fluorine based) is then typically used to pattern through the relatively thin hardmask layer, using the pre-patterned PR layer as the pattern-proliferating mask. This is done before metal etching commences through a substantially thicker and underlying metal layer. The lithographic pattern that is imprinted into the PR layer is therefore first copied into the stronger, hardmask layer and then the pattern in the stronger, hardmask layer is used to further project the pattern into the lower, metal stack layer.

Since the relatively stronger hardmask layer is able to better withstand the erosive environment of the metal etch process than can the upper PR layer, a thicker amount of underlying metal can be patterned than would otherwise be possible with use of just the organic PR layer. Additionally, the patterned hardmask layer may be retained in some instances to serve as an inter-metal dielectric which protects the upper surface of the metal lines from post-etch corrosion.

A variety of different materials may be used for defining the upper PR layer and for defining the underlying hardmask layer, as well as any surrounding anti-reflection coatings (ARC layers). It has been proposed that Tetra-Ethyl-OrthoSilicate (TEOS), and more particularly, Plasma-Enhanced TEOS (PE-TEOS) might be used for forming a blank hardmask layer on top of a titanium (Ti) containing ARC layer (anti-reflection coating). In one embodiment, the post-etch PE-TEOS is intended to be used as a retained inter-metal dielectric. However, it has been observed that a significant amount of micromasking residue may be left behind on the Ti-containing ARC layer and that this micromasking residue can interfere with proper etching of the underlying metal (e.g., aluminum) layer. More specifically, the residue may create undesirable short circuits between metal interconnect lines.

The below disclosure reveals a mechanism that is thought to be at least partly responsible for generating the interfering residue. The below disclosure provides methods for reducing the amount of, or for eliminating such micromasking residue and/or for preventively reducing the formed amount of such micromasking residue.

### INTRODUCTORY SUMMARY

Structures and methods may be provided in accordance with the present disclosure of invention for reducing the amount of, or for eliminating titanium-oxide and/or titanium-fluoride containing residue and/or for preventively reducing the formed amount of such micromasking residue.

More specifically, it has been observed that the micromasking residue includes nodule-shaped regions and that among other elements the micromasking residue contains substantial amounts of titanium and oxygen, typically in the compound form of TiO₂. In addition to the nodule-shaped regions it is possible for the residue to contain smaller, nanofiber-shaped regions; however, these alone are unlikely to contribute to creating continuous short circuits between metal lines. It is proposed that titanium diffusion from a titanium-containing ARC layer (and/or other forms of introduction of titanium) may combine with oxygen diffusion from the TEOS hardmask layer (and/or other forms of introduction of oxygen) at the locations where micromasking residue is observed to thereby produce the TiO₂ component of the micromasking residue material. It is postulated that positional inversion and/or inter-curling of oxygen-dominated material (e.g., TEOS) with metal-dominated material (e.g., TiN) may occur at the TEOS-to-ARC interface and that such inversion/curling may produce the etch-resistant residue seen at the micromasking sites. In other words, if the desired vertical sequence of oxide material (TEOS) on top and ARC metal material (Ti, TiN, TiW) on the bottom, flips upside down in small regions, the small amount of on-top metal material (Ti-or TiF compounds/complexes as shall be explained below) may shield the TiO₂ component of the micromasking residue material from being etched during etching of the main TEOS body. Then the preserved TiO₂ and/or other oxide component of the residue can shield the underlying metal material from being etched during etching of the main metal body, thereby leaving behind undesired, micromasked metal interconnect.

More particularly, it is postulated that interfacial curling and/or material inversion may be responsible for producing the observed titanium-dioxide and/or other titanium oxides or titanium compounds at the micromasking sites. It is postulated that the formed titanium oxides/compounds aggregate to lay under titanium-fluoride (TiF and/or other compounds of titanium and fluorine) shrouds to thereby create residue-like nodules and/or fibers. It is observed that the formed nodules can resist normal removal by the normally used sequence of etch recipes for oxide on top of metal (etch oxide first and then etch the underlying metal stack). The TiF compound shrouds may form during etching of the oxide hardmask. It is surmised that base portions (e.g., bottom stems) of the observed micromasking nodules tend to be more rich in titanium while the upper parts of the nodules tend to be more rich in oxygen and/or fluorine and that the middle sections of the micromasking nodules tend to include compounds and/or complexes of the form, Tiₓ—O_{y}—F_{z} where x>0, y>0 and z≧0. Given this, it was postulated that the metal-rich base portions (e.g., bottom stems) of the micromasking nodules/fibers might be weakened by isotropic attack from a chemical that volatilizes titanium (e.g., chlorine). It was further postulated that the oxide-rich body portions of the micromasking nodules/fibers might be simultaneously or thereafter detached from their weakened bases by physical bombardment. Results from treatment with a plasma containing chlorine and argon appear to support this hypothesis.

In accordance with the disclosure, a volatilizing agent (e.g., chlorine) is used for chemically reacting with titanium-rich parts of the micromasking nodules (e.g., the titanium-rich, bottom stems) while a mechanical bombardment plasma component (e.g., argon) is simultaneously or thereafter used to further weaken the micromasking nodules and break them off from their anchor points. In one embodiment, a plasma etch tool is operated with an inflow gas mixture of about 20 sccm chlorine and about 80 sccm argon (a Cl₂/Ar flow ratio of about 1/4) for about 10 seconds at a plasma RF power setting of about 400 watts and a pedestal power setting of about 100 W to effectively remove micromasking residue from a 375 Å thick TiN ARC layer after an overlying PE-TEOS hardmask has been etched with a fluorine-based recipe. Other nodule-volatizing agents (in place of, or in addition to chlorine) may be used in combination with the same or other mechanical bombardment agents to remove the residue. Among the alternative or additional agents which may be used are one or more other noble gases besides argon, such as Ne or Kr in appropriate mixtures for providing an average bombardment mass that does not cause excessive damage to underlying layers. The other agents may also include HCl, BCl₃ and SiCl₄. The used agents should not contain substantial amounts of fluorine (F) because TiF compounds can be relatively nonvolatile in the pressure/temperature ranges used in some plasma tools. Formation of TiF and/or other titanium fluorine compounds may impede removal of the micromasking residue.

A residue preventing and/or reducing method in accordance with the disclosure may include providing an oxygen-starved layer such as SiON and/or SiN between the TEOS hardmask layer and the titanium-containing ARC layer so as to reduce or prevent the formation of titanium-oxide fibers/nodules at the interface.

A monolithic integrated circuit device in accordance with the disclosure includes an inter-metal dielectric wherein a TEOS hardmask interfaces with a titanium-containing upper part of a patterned metal stack. The interface between the TEOS hardmask and the titanium-containing upper part may include nodules having a titanium-oxide compounds.

Other aspects of the disclosure will become apparent from the below detailed description.

### BRIEF DESCRIPTION OF THE DRAWINGS

The below detailed description section makes reference to the accompanying drawings, in which:

FIG. 1 is a schematic cross sectional view (not to scale) showing a TEOS-covered metal stack with a photoresist (PR) layer provided above, where the PR layer is being exposed to patterning radiation;

FIG. 2A is a schematic cross sectional view showing the TEOS-covered metal stack after the TEOS hardmask has been etched and residue nodules have been exposed;

FIG. 2B is a schematic cross sectional view showing the TEOS-covered metal stack after the metal stack has been etched and residue nodules have created a micromasked short circuit;

FIG. 3 is a combination flow chart and magnified cross sectional view showing a possible mechanism by way of which titanium-oxide containing nodules may be removed; and

FIG. 4 is a schematic cross sectional view showing a hardmask-covered metal stack with an oxygen-poor layer interposed between the hardmask and the metal stack.

### DETAILED DESCRIPTION

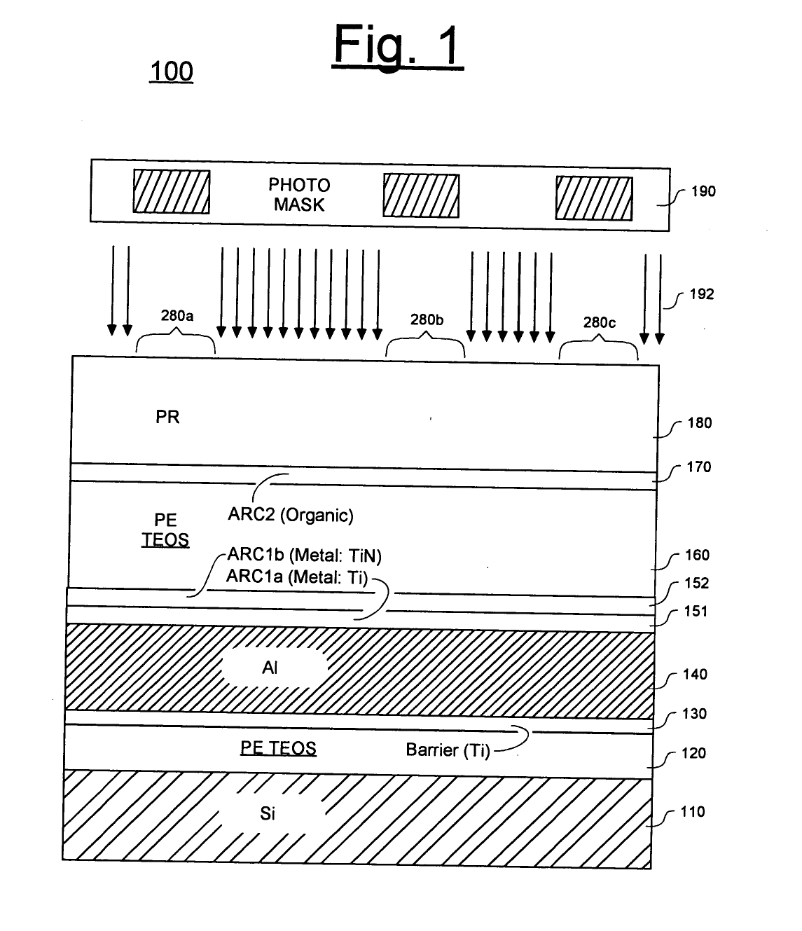

FIG. 1 is a schematic cross sectional view (not to scale) showing an in-process semiconductor wafer 100. The in-process wafer 100 has a TEOS-covered metal stack 130-152 and it further has a photoresist overlayer 180 disposed above the metal stack 130-152. In FIG. 1, the PR layer 180 is being exposed to patterning radiation 192 passing through a predefined photolithography mask 190. Opaque and transparent regions of the photolithography mask 190 may be swapped depending on whether positive or negative resist chemistries are used. In the illustrated example, columnar regions 280a, 280b and 280c are to remain after PR development.

The illustrated metal stack of FIG. 1 includes a first titanium layer 130 (e.g., about 120 Å thick) which is intended to function as a barrier layer between an overlying aluminum alloy layer 140 (e.g., 0.5% Cu, about 0.38 μm thick) and an underlying, first PE-TEOS layer 120 (Plasma-Enhanced TEOS). The first PE-TEOS layer 120 may be disposed over a monocrystalline silicon substrate 110. Active devices such as transistors (not shown) may be defined in or on the Si substrate 110. (Other types of semiconductor containing substrates may be used instead including those with polysilicon, SiGe, etc.) The Al layer 140 and Ti barrier layer are to be patterned to define metal interconnect between various active and/or passive electrical components (not shown) of the monolithically integrated circuit device that is being fabricated. Vias (not shown) may be provided through the first PE-TEOS layer 120 for making contact with the various electrical components. The illustrated photolithography mask 190 is understood to have appropriate patterning features provided thereon (positive or negative image) for forming the desired metal interconnect patterns in the metal stack 130-152.

In one embodiment, the metal stack includes a first metal, ARC-barrier layer 151 (ARC layer 1a) composed of Ti and having a thickness of about 60 Å. The metal stack further includes a second metal ARC layer 152 (ARC layer 1b) composed of TiN and having a thickness of about 375 Å. These ARC-1 a (151) and ARC-1 b (152) layers are disposed above the main metal interconnect layer (140). The specific compositions and thicknesses of the main metal interconnect layer (140) and the ARC-1 a layer (151) and the ARC-1 b layer (152) may vary with design. More specifically, the metal ARC layer or layers will often contain titanium and/or titanium compounds or alloys such as TiN and TiW. The main metal interconnect layer (140) will typically contain aluminum and/or compounds or alloys of aluminum such as AlCu.

In the same embodiment, a second PE-TEOS layer 160 (Plasma-Enhanced TEOS) has been deposited by plasma deposition on the metal stack 130-152 to a thickness of about 0.12 μm. This second PE-TEOS layer 160 is intend d to serve as a hardmask for subsequent etching of the metal stack 130-152. Parts of the second PE-TEOS layer 160 may also be retained to serve as inter-metal dielectric between retained portions of the metal stack 130-152 and another metal layer (not shown) formed later in the fabricating of the IC device.

Further in FIG. 1, an organic ARC layer (ARC-2) 170 having a thickness of about 780 Å has been deposited on the second PE-TEOS layer 160. A photoresist such as a UV-sensitive photoresist 180 (e.g., UV6) having a thickness of about 0.61 μm has been deposited on the ARC-2 layer 170. The PR layer 180 includes organic compounds which may be volatilized during subsequent plasma processing steps.

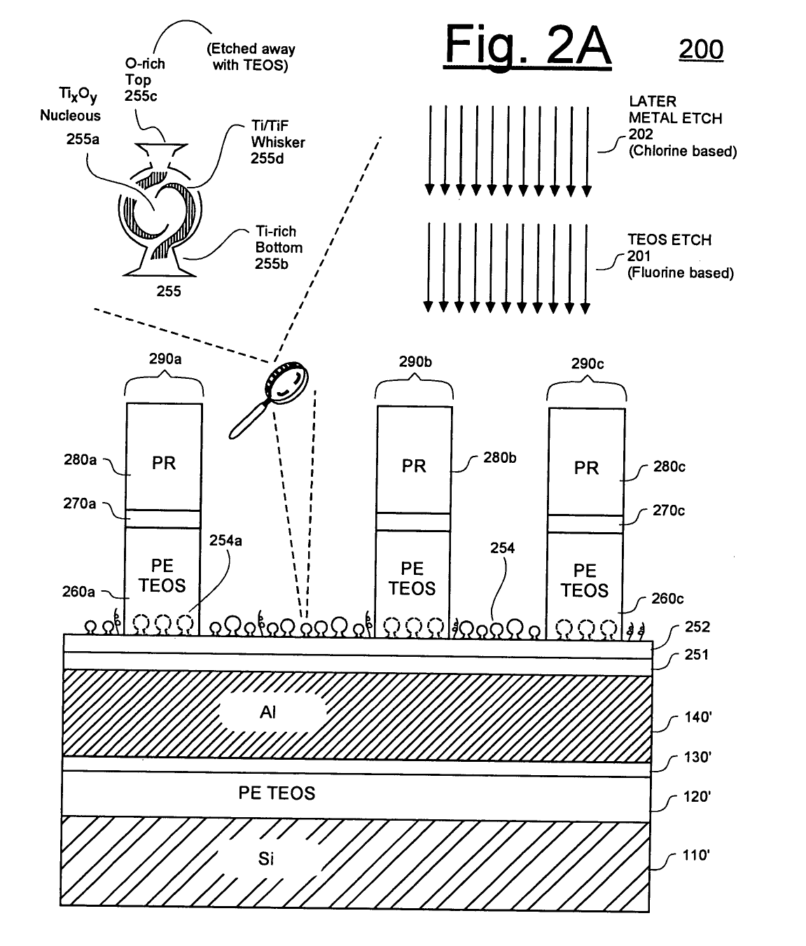

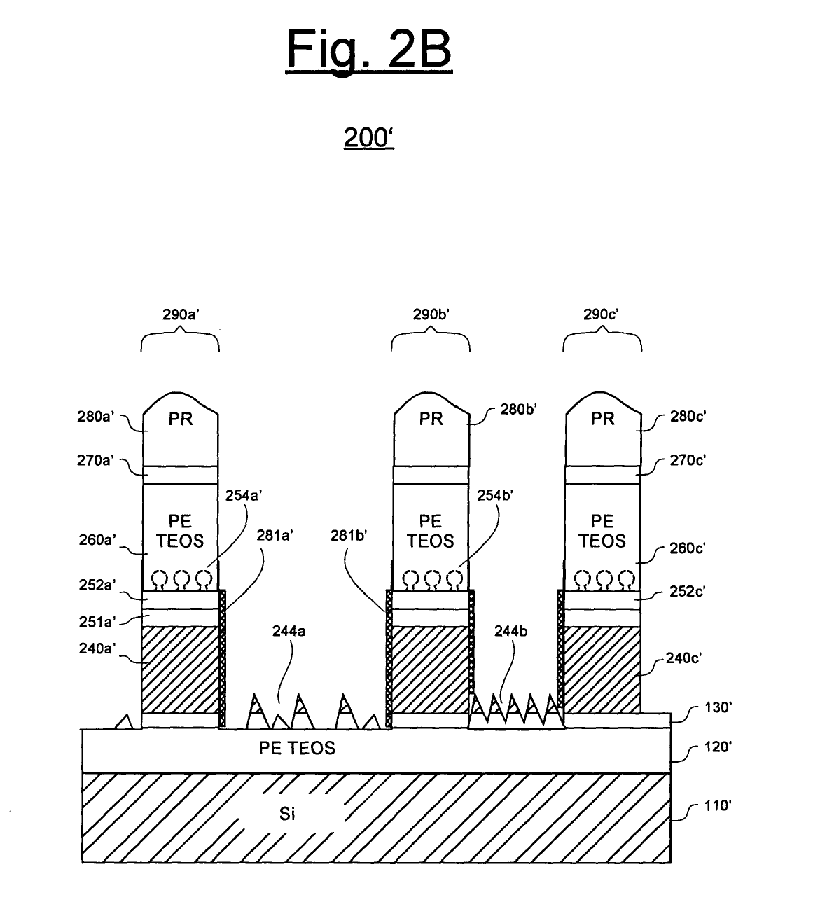

Referring to FIG. 2A, following the development of the exposed PR layer 180 (FIG. 1), a TEOS etch 201 is performed with a fluorine containing plasma to leave behind the illustrated three columns, 290a, 290b and 290c of organic and oxide material. The latter three columns are the PR-protected remnants of corresponding regions 280a, 280b and 280c of FIG. 1.

Scanning electron microscopic (SEM) inspection of the top of the ARC-1 b layer 252 often reveals a large multitude of residual nodules 254. Nanofibers may also be included in the exposed residue 254, however these are typically not seen at the magnification used to spot the residual nodules 254. The schematic assumes most of the residue to be in nodule form. These nodules 254 (shown only in schematic form) tend to vary randomly in size and location, with the average observable ones being clumps having a diameter of about 100 Å, with the more scarce, but larger ones having diameters of about 500 Å each, and with the more numerous but smaller ones appearing to have diameters of about 50 Å or less each. Although such nodules are not directly observed as being present in the interface between the intentionally left-intact hardmask TEOS sections 260a-260c, it may be reasonably expected that such buried nodules 254a may be present there as well. (The buried-in-interface nodules 254a can be somewhat different from the exposed nodules 254 because the buried nodules 254a are not subjected to the fluorine-containing TEOS etch process 201.)

Chemical analysis of the exposed residue material (254) was performed using X-ray photoelectron spectroscopy (XPS) and electron spectroscopy for chemical analysis (ESCA). Such chemical analysis service may be obtained from the XPS Services division of Charles Evans & Associates of California. The XPS/ESCA analyses indicated that the residue contaminated surface of the exposed ARC-1b layer 252 (TiN) contained a significant amount of titanium dioxide (TiO₂). Smaller amounts of what is believed to be TiF₃ and/or TiF₄ were also detected by the XPS/ESCA analyses. TiO and Ti₂O₃ were also detected as well as small amounts of compounds of the form TiₓO_{y}N_{z}. Fluorinated carbons were also detected, as would be expected due to the exposure of PR sections 280a-280c to the fluorine-based plasma that anisotropically etched the PE-TEOS layer to leave behind TEOS sections 260a-260c.

When a chlorine-based metal etch is subsequently performed (e.g., metal etch 202), it is observed that a number of the residual nodules 254 behave as if they were tiny islands of etch-resisting oxide. They prevent the underlying metal (140′) from being etched. Hence they are referred to as micromasking nodules. If a continuous string of such micromasking nodules occurs between two or more of mask columns 290a-290c, undesired electrical shorts 244 (see FIG. 2B) may develop between the mask-covered portions of the metal stack. Even if complete shorts are not formed, critical electrical attributes of the interconnect such as parasitic capacitance and/or current leakage may be adversely affected by micromasking.

The XPS/ESCA analyses did not directly indicate what the exact composition and structure of the micromasking nodules/fibers 254 might be. Nonetheless, because of their size, shape, distribution and behavior, it may be reasonably surmised that this residue material 254 is resistant to the ordered and sequential carrying out of the TEOS etch 201 (fluorine-based) and of the subsequent metal etch 202 (chlorine-based). Therefore, some of the titanium-oxide(s) and/or titanium-fluorides and/or other constituent parts of the residue 254 which remain after the TEOS etch step 201 (fluorine-based) provide resistance against the chemically-reactive, chlorine-based plasma that is used in metal etch step 202. It is possible that some type of protective umbrella or shrouding mechanism (see 255d of FIG. 2A) develops above remnant oxide portions (255a) of the residue to protect them from removal by the TEOS etch step 201 (fluorine-based). It is possible that some of the formed compounds (TiₓO_{y}N_{z}) or complexes in the residue are resistant to chemical removal by chlorine and/or fluorine based etch plasmas.

Referring to magnification 255 in FIG. 2A, it is possible that production of the observed TiO₂ and/or other components of the micromasking residue 254 may have arisen from interfacial diffusion of Ti atoms (and/or from other introduction of titanium, for example by whisker protrusion) from the underlying ARC-1b and/or ARC-1a layers (252, 251 respectively) into the micromasking sites 254. Production of the observed TiO₂ may further arise from diffusion of (and/or from other introduction of) oxygen atoms into the micromasking sites 254 from the overlying PE-TEOS layer 160. The specific ratio of titanium to oxygen (TiₓO_{y}) within the micromasking nodules 254 can vary. There may also be Ti—O—Si complexes that temporarily develop in the region of the observed residue. The XPS/ESCA analyses did not reveal specific peaks for such complexes.

Magnification 255 proposes possible structure(s) and/or formation mechanism(s) for the nodular ones of the observed micromasking residue elements 254. It is possible that a titanium-rich, bottom diffusion path 255b (and/or a titanium containing whisker 255d) rises up from the planarized ARC layer(s), 251-252 to intersect with an oxygen-rich, top diffusion path 255c which descends from the PE-TEOS layer 160 (FIG. 1) and/or that the titanium-containing whisker/diffusion-path 255d/255b enters into an oxygen-supplying fracture within the PE-TEOS material. The confluence of the titanium-providing means 255b/255d and the oxygen-providing means 255c may swirl about and/or meet near the center of the TiₓO_{y} nucleation site 255a, where site 255a is later seen as the main body of the observed micromasking nodule 255. During the TEOS etch 201, the oxygen-rich part of the oxygen-providing means 255c is probably eroded away to leave behind the TiₓO_{y} nucleation region 255a and a titanium-rich, bottom stem or base 255b. The top of the titanium-providing means 255b/255d may form a Ti or TiₓF_{y} protective shroud over the TiₓO_{y} nucleation region 255a. TiₓF_{y} compounds can be nonvolatile solids under these conditions and the XPS/ESCA analyses did indicate presence of some TiF compounds. The fluorine may have come from the fluorine-based TEOS etch 201. Nucleation region 255a may include TiₓO_{y}F_{z} and/or TiₓO_{y}N_{z} where x>0 and at least one of y and z is also greater than zero. The XPS/ESCA analyses did indicate presence of TiₓO_{y}N_{z} complexes. We do not have conclusive photomicrographs of the proposed stem/base and nucleus arrangement and therefore the structure(s) and mechanism(s) of formation for the micromasking nodules are deduced from behavioral observations rather than being directly determined.

Typically in the metal etch step 202 that follows exposure of the exposed, micromasking nodules 254, the ARC-1a, ARC-1b and aluminum layers (252, 251, 140′) will be attacked by a plasma mixture containing nitrogen (N₂), BCl₃ and chlorine (Cl₂). However, for reasons that are not fully understood, the micromasking nodules/fibers 254 appear to resist uniform removal with such treatment. FIG. 2B is a schematic cross sectional view showing the TEOS-covered metal stack after the metal stack has been etched and some of the residue nodules have created a micromasked short circuit 244b. In the embodiment 200′ of FIG. 2B the organic PR sections 280a-280c of FIG. 2A have been left in place at the start of the metal etching step 202. In FIG. 2B, these kept PR sections 280a′-280c′ are shown to have been partially eroded away by the metal etch step 202. (They can also be fully eroded away.) Part of the organic material which eroded away from the PR sections 280a-280c forms a protective sidewall coating (e.g., 281a′-281b′) along the etched metal 130′, 240′-252′ that remains behind. Th sidewall coating organic material can provide protection against undercutting and/or corrosion. Additionally or alternatively, the sidewall passivating coating 281a′ may come from carbonaceous materials that are admixed into the metal-etching plasma (202). If the input gases to the metal-etching plasma (202) provide the sidewall passivation, then PR layer 280 (FIG. 2A) may be stripped away after the hardmask 260 is patterned and before metal-etching begins.

It has been found through experimentation that a residue removing step may be carried out before the metal-ARC removal step 202. It has been found that essentially all of the exposed, micromasking nodules 254 may be removed by such a residue removing step. As a result, micromasking-created short circuits such as the one shown at 244b are prevented. In one embodiment, the residue removing step is carried out in a Lam 9600 SE™ tool (available from Lam Research Corporation of California, USA) with an inflow gas mixture of about 20 sccm chlorine (Cl₂, measured in standard cubic centimeters per minute) and about 80 sccm argon (Ar) for about 10 seconds at a plasma RF power setting of about 400 watts (13.56 MHz), a pedestal bias power setting of about 100 watts (13.56 MHz), a chamber pressure of about 12 milliTorr, and a backside helium cooling pressure of about 8 Torr. This residue pre-clean was part of a larger in-tool recipe given by the following Table 1.

TABLE 1
Lam 9600 SE ™ tool recipe for Al stack etch and Residue pre-clean

| Step | Press- | Plasma | Bias | Gas1 | Gas2 | Gas3 | Gas4 | Back | | |
|---|---|---|---|---|---|---|---|---|---|---|
| Name | ure | (watts) | (watts) | (sccm) | (sccm) | (sccm) | (sccm) | side | Time | Temp |
| Residue | 12 | 400 | 100 | Cl2 | Ar | | | 8 T | 10 | |
| Pre-clean | mT | | | (20) | (80) | | | | sec | |
| Initial ARC | 11 | 400 | 100 | Cl2 | BCl3 | N2 | | 8 T | 5 | |
| remove | mT | | | (50) | (50) | (6) | | | sec | |
| Al etch | 10 | 500 | 200 | Cl2 | BCl3 | Ar | N2 | 8 T | End | |
| | mT | | | (45) | (25) | (20) | (10) | | Point | |
| Over | 10 | 500 | 250 | Cl2 | BCl3 | Ar | N2 | 8 T | 25 | |
| etch 1 | mT | | | (22) | (28) | (20) | (10) | | sec | |
| Over | 10 | 400 | 250 | Cl2 | BCl3 | Ar | N2 | 8 T | 15 | 60 C. |
| etch 2 | mT | | | (20) | (35) | (50) | (10) | | sec | |

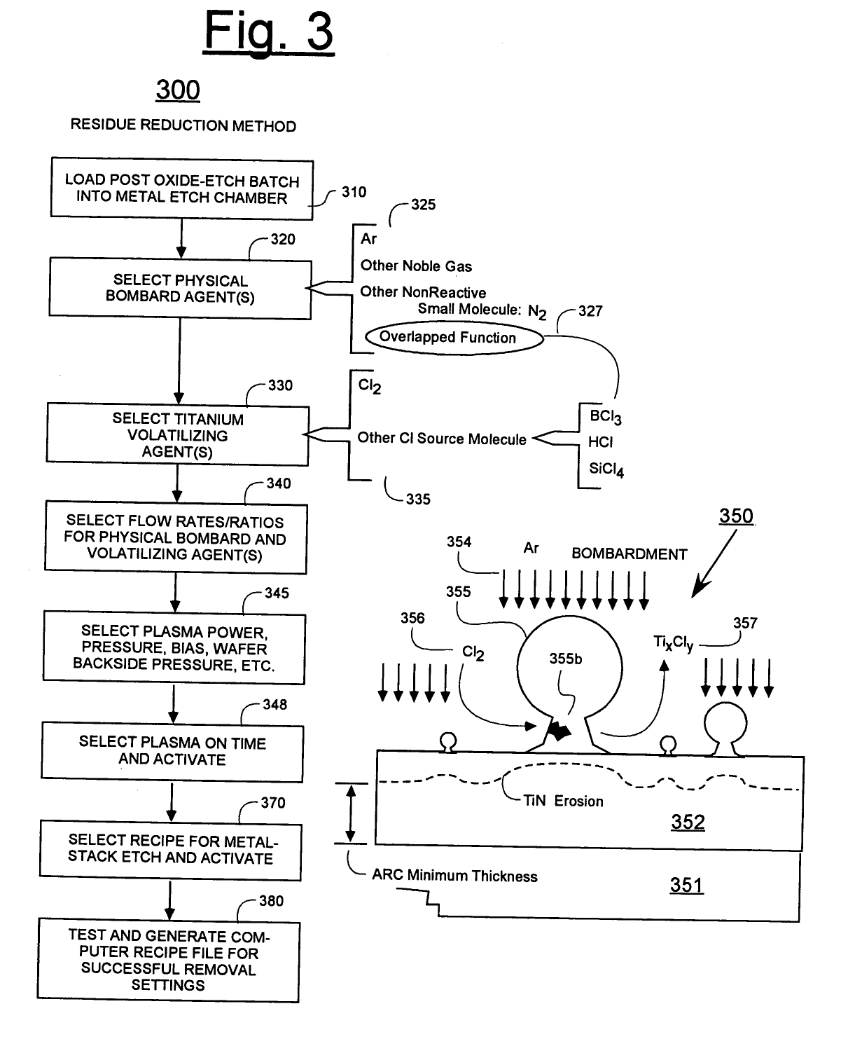

FIG. 3 is a combination flow chart 300 and showing of magnified cross sectional view 350 of a possible mechanism by way of which micromasking nodules may be removed. It is believed that a small-sized, chemically-reactive species such as chlorine 356 can find its way by diffusion or otherwise to come into reactive proximity with the bottom stems or bases 355b of the micromasking nodules/fibers (355) and to begin to chemically remove the stem/base material. For example, titanium in the base material can react with the base-attacking chlorine to form volatile titanium-chlorine compounds (TiₓCl_{y}) 357 such as TiCl₂ gas. At the same time (or a later time), physical bombardment 354 by a nonchemically-reactive and relatively low mass species such as argon can stress the upper parts of the stem/base-supported micromasking nodules 355. The combined mechanical stress from above and chemical attack at the bottom stems/bases 355b appears to provide the desired result of breaking the nodules 355 away from their anchor points and removing them from the underlying metal ARC layer 352 without causing undue damage to underlying layers. Various formulations of chemically-reactive and mechanically-active agents may be used in addition to or as alternatives to the Cl₂/Ar combination. These may include HCl, BCl₃, and/or SiCl₄ as additional or alternate sources of the chlorine reactant. These may further include He, Ne, and/or Kr as additional or alternate sources of the physical bombardment agent. BCl₃ may provide a dual role of providing both reactive chlorine and acting as a physical bombardment agent. Various parameter ranges may be used for the corresponding residue cleaning plasma, including but not limited to: a pressure range of about 2 mT to about 15 mT (or more preferably, about 6 mT to about 12 mT); a plasma power range of about 300 watts to about 600 watts; a pedestal bias power of about 80 watts to about 200 watts; a residue removal time (e.g., plasma on time) of about 3 seconds to about 20 seconds (or more preferably, about 8 seconds to about 15 seconds); an input flow rate for the chemically-reactive small molecule gas (e.g., argon) of about 50 sccm to about 150 sccm; and/or an input flow rate for the mechanically-active small molecule gas (e.g., chlorine) of about 10 sccm to about 50 sccm. The volumetric flow rate ratio of the chemically reactive, base-attacking species (e.g., chlorine) to the relatively low average mass, physical bombardment species (e.g., argon) may be in the range of about 1:10 to about 4:10. More preferably, the volumetric flow rate ratio may be in the range of about 2:10 to about 3:10. In the case of chlorine and argon, a respective volumetric flow rate ratio of about 1:4 (25%) was found to be effective.

It is to be appreciated from FIG. 3 that the residue nodules typically each have a base or bottom stem (255b,355b) and an upper body portion (255a,255d). Access of the chemically reactive agent (e.g., chlorine) to the base or bottom stems may be limited due to crowding by adjacent nodules and/or fibers or due to short stem height. In order to better assure that the chemically reactive, plasma agent (356) moves into appropriate reactive-proximity with the bases/stems of the nodules, it is desirable to include a chemically reactive, plasma agent that is of relatively small diameter, for example, ionized chlorine atoms. In other words, in order for the chemically reactive, plasma agent to diffuse into reaction zones surrounding the bases or stems of the residue nodules and/or fibers so as to react with the metal element (e.g., Ti), if any, in those respective bases/stems of the residue nodules and/or fibers, it is desirable to have the chemically reactive, plasma agent be one of a relatively small physical size. Chlorine appears to work well in this role. It is possible in many cases for HCl to also be of sufficiently small size to easily diffuse into the stem reaction zones. Mixtures of Cl₂ and HCl may be used. Larger sized reactive agents, such as BCl₃ and/or SiCl₄ may not be able to get into tightly crowded stem reaction zones. They may however reach less crowded ones. Accordingly, if larger sized reactive agents, such as BCl₃ and/or SiCl₄ are used, it may be advisable to use them in combination with smaller sized agents such as Cl₂ and/or HCl so that tighter stem reaction zones will be operatively reached at least by the smaller sized reactive agents.

FIG. 3 shows a residue reducing or removing process 300 in accordance with the disclosure as optionally including a first step 310 of loading a post-oxide etch batch of in-process wafers (e.g., 200 of FIG. 2) into a metal etching tool chamber (e.g., into a Lam 9600 SE™ tool).

A second step 320 in the process may be that of selecting one or more physical bombardment agents such as Ar and/or other noble gases and/or other, relatively low-mass non-reactive molecules such as is indicated in options are 325 of the flow chart. (Alternatively, one or a plurality of physical bombardment agents may be fixedly pre-selected.) It is believed that a relatively low-mass species (Ar and/or Ne) should be used for the physical bombardment agent(s) because this non-selective agent (354) can also remove part of the underlying ARC layer 352 (e.g., as indicated by the dashed TiN erosion profile). In other words, a balance should be struck between having too low of an average physical bombardment mass (e.g., by using only helium) such that the micromasking nodules are not broken away from their anchors; and having too high of an average physical bombardment mass (e.g., by using Xe alone as the nonselective bombardment agent) such that excessive damage is done to underlying layers. The relatively small, average mass of the selected physical bombardment agents should be such as to limit undesirable removal of material from the underlying ARC layer(s) 352-351. Subsequent processes may call for preservation of a predefined minimum thickness of the underlying ARC layer(s) 352-351. The mass, flow rate and kinetic energies of the selected physical bombardment agent(s) should be configured so that the recipe prescribed, minimum ARC thickness is preserved within allowed tolerances of cross-wafer planarity and/or other such attributes. Although nitrogen (N₂) may be some what reactive, it too may be considered as a candidate for providing kinetic bombardment energy.

A third step 330 in the process may be that of selecting one or more chemically-volatilizing agents such as Cl₂ which react with the titanium-rich stems 355b of the micromasking nodules/fibers and produce a volatile reaction product 357 such as TiCl₂, which reaction product 357 (TiₓCl_{y}) then flows away from the anchor site 355b. The selection options 335 for step 330 may include selecting a mixture of two or more of Cl₂, HCl, BCl₃ and SiCl₄. A molecule such as BCl₃ may serve an overlapping function as a bombardment species and the source of the chemically reactive chlorine for reaching the stem reaction zones. (As an alternative to selection step 330, one or a plurality of chemically-reactive agents may be fixedly pre-selected.) The selected, chemically-volatilizing agent (356) should, of course, be able to operatively come into proximity with the stem/base reaction zones and it should be able to selectively volatize the stems/bases 355b of the residue nodules 355 without substantially eroding away the underlying ARC layer(s) 352-351. The mass, flow rate and kinetic energies of the selected chemically-active removal agent(s) should be configured so that the recipe prescribed, minimum ARC thickness is preserved within allowed tolerances of cross-wafer planarity and/or other such attributes. It is believed that a relatively small-diameter species should be used for the chemically-active removal agent(s) because these selective agent(s) (354) have to diffuse into the spaces where the metal-rich, bottom stems 355b extend from anchoring points in the underlying ARC layer(s) 352-351 to the upper bodies of the respective micromasking nodules/fibers. In some cases, BCl₃ and SiCl₄ may be too large to do the job whereas HCl may be better able to provide small-sized Cl radicals near the anchor sites.

In the fourth optional step 340 of process 300, the respective flow rates for the select d, physical-bombardment and chemically-reactive agents are established. As implied above, the selected flow rates may vary depending on what concentrations of chemically-volatilizing agents (e.g., Cl₂) are to reach the metal-rich anchor sites 355b and what limits are imposed on coincidental erosion of the underlying ARC layer(s) 352-351. In the fifth optional step 345 of process 300, respective other parameters of residue-reducing/cleaning plasma step are selected such as RF power, bias power, pressure, etc. Once again, these various parameters may be changed depending on what concentrations of chemically-volatilizing agents (e.g., Cl₂) are to reach the metal-rich anchor sites 355b, what amount of kinetic bombardment energy is empirically found to be sufficient for dislodging the weakened-stem nodules/fibers and what limits are imposed on coincidental erosion of the underlying ARC layer(s) 352-351. In step 348, the plasma on-time for the selected other recipe components is selected. The residue-removing recipe is then carried out accordingly.

Step 370 of process 300 represents the defining of subsequent metal-etch recipes that may be carried out in the same tool chamber (see step 310) as that used for the residue-removing recipe (320-348). The subsequent metal-etch recipes (see the above Table 1) may affect the choices made in steps 320-348 because there can be some overlap of kinetic bombardment functionality between the pre-etch cleaning step and the metal stack etching steps. Also it may be economic to use one or more same reactive gases (e.g., chlorine) in both processes.

Step 380 represents the creation of a computer-readable control file which is usable for causing the etch tool to automatically carry out the recipe(s) established in steps 320-348 and optionally also step 370. Typically the etch tool computer will have a predefined one or more acceptable formats in which it expects to receive automated recipes. Accordingly, step 380 may including the providing of the recipe(s) established in steps 320-348 and optionally step 370 according the tool-accepted format(s). Once a particular set of settings has been empirically found through testing to be effective for residue removal or reduction in a first tool, the computer generated recipe file of step 380 may be copied to other like tools for replication of the residue removal/reduction method 320-348 in those other, like tools.

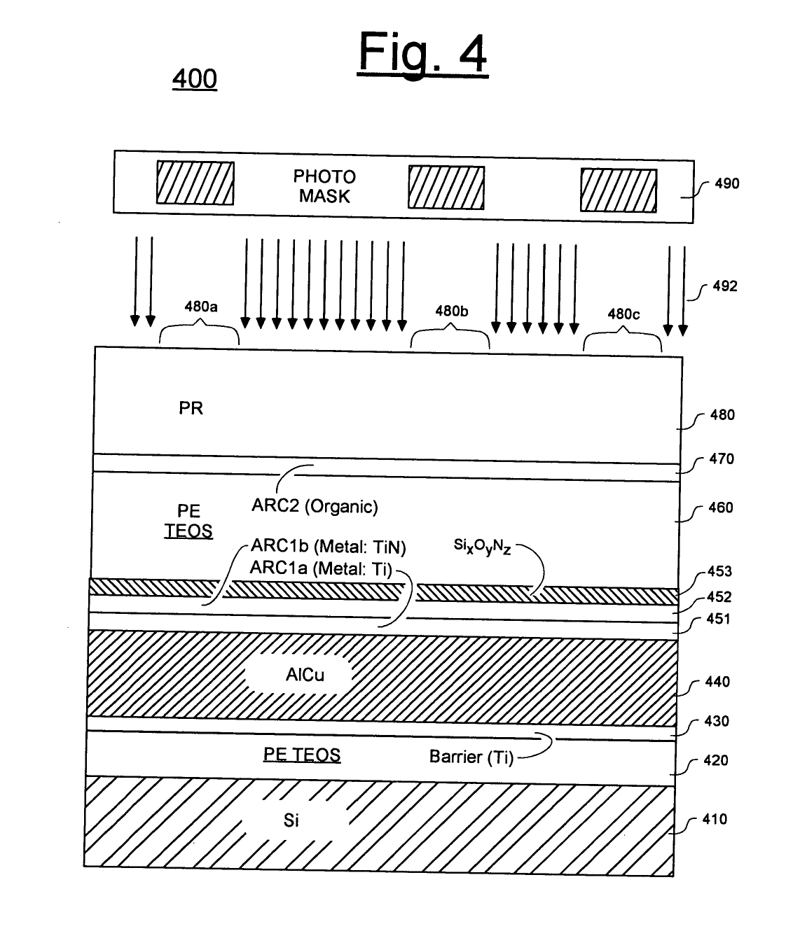

The above observations and postulated mechanisms indicate that production of micromasking nodules/fibers may be reduced or mitigated by reducing the amount of oxygen available at the interface of the hardmask and the metal ARC layers. FIG. 4 proposes a modified interface between the hardmask and the metal ARC layers. Where practical, like reference symbols and numbers in the “400” century series are used for elements of FIG. 4 which correspond to but are not necessarily the same as the elements represented by similar symbols and reference numbers of the “100” century series in FIG. 1. As such, a detailed description of all the elements found in FIG. 4 may be omitted here. The difference is that a SiₓO_{y}N_{z} interfacial layer 453 is interposed between the PE-TEOS layer 460 and the titanium-containing ARC layers 452-451, where x>0, z≧0 and where the density of oxygen in layer 453, as is represented by y in the formulation (SiₓO_{y}N_{z}) is less than the density of oxygen within the adjacent PE-TEOS layer 460. As such, less oxygen is available for forming micromasking nodules of the formulation Ti_{x′}O_{y′}F_{z′} where x′>0, y′>0 and z′≧0. If both y and z are zero in the formulation, SiₓO_{y}N_{z} then layer 453 becomes simply silicon (typically polycrystalline). If z=0, then the ratio of y:x should be substantially less than 2:1 (e.g., less than about 1:1). The oxygen-poor SiₓO_{y}N_{z} layer 453 may have a thickness in the range of about 60 Å to 200 Å (in other words, a thickness less than that of the combined metal ARC layers 451-452). In some applications, a thicker layer 453 of SiON may be used. The SiON layer can function as one or both of an ARC layer and a hardmask layer. The optical dielectric properties of the oxygen-poor SiₓO_{y}N_{z} layer 453 may be tailored by adjusting y and z so as to augment the anti-reflection functions of ARC layer 451 and 452.

The present disclosure is to be taken as illustrative rather than as limiting the scope, nature, or spirit of the subject matter claimed below. Numerous modifications and variations will become apparent to those skilled in the art after studying the disclosure, including use of equivalent functional and/or structural substitutes for elements described herein, use of equivalent functional couplings for couplings described herein, and/or use of equivalent functional steps for steps described herein. Such insubstantial variations are to be considered within the scope of what is contemplated here. Moreover, if plural examples are given for specific means, or steps, and extrapolation between and/or beyond such given examples is obvious in view of the present disclosure, then the disclosure is to be deemed as effectively disclosing and thus covering at least such extrapolations.

By way of an example, it is understood that the configuring of a metal etch tool in accordance with the disclosure can include use of one or more computers for carrying out automated removal of undesirable micromasking residue. A computer-readable medium (e.g., manufactured in step 380 of FIG. 3) or another form of a software product or machine-instructing means (including but not limited to, a hard disk, a compact disk, a flash memory stick, a downloading of manufactured instructing signals over a network and/or the use of like software products) may be used for instructing an instructable machine (e.g., etch tool) to carry out such residue removing activities (e.g., 320-348), where the instructed activities can include any one or more of the agent and/or plasma parameter selecting steps in accordance with the disclosure where the configuration data defines configuration signals which can be loaded via a programming device. As such, it is within the scope of the disclosure to have an instructable machine carry out, and/or to provide a software product adapted for causing an instructable tool to carry out a machine-implemented method comprising: (a) selecting a physical bombardment agent for use in residue removal; (b) selecting a chemically-reactive agent for use in residue removal; (c) defining the flow rates over time of the selected physical bombardment and chemically-reactive agents as they are used for residue removal; (d) defining one or more plasma power values to be used for residue removal; (e) defining one or more plasma chamber pressure values to be used for residue removal; and (f) defining one or more plasma activation durations to be used for residue removal.

Reservation of Extra-Patent Rights, Resolution of Conflicts, and Interpretation of Terms

After this disclosure is lawfully published, the owner of the present patent application has no objection to the reproduction by others of textual and graphic materials contained herein provided such reproduction is for the limited purpose of understanding the present disclosure of invention and of thereby promoting the useful arts and sciences. The owner does not however disclaim any other rights that may be lawfully associated with the disclosed materials, including but not limited to, copyrights in any computer program listings or art works or other works provided herein, and to trademark or trade dress rights that may be associated with coined terms or art works provided herein and to other otherwise-protectable subject matter included herein or otherwise derivable herefrom.

If any disclosures are incorporated herein by reference and such incorporated disclosures conflict in part or whole with the present disclosure, then to the extent of conflict, and/or broader disclosure, and/or broader definition of terms, the present disclosure controls. If such incorporated disclosures conflict in part or whole with one another, then to the extent of conflict, the later-dated disclosure controls.

Unless expressly stated otherwise herein, ordinary terms have their corresponding ordinary meanings within the respective contexts of their presentations, and ordinary terms of art have their corresponding regular meanings within the relevant technical arts and within the respective contexts of their presentations herein.

Given the above disclosure of general concepts and specific embodiments, the scope of protection sought is to be defined by the claims appended hereto. The issued claims are not to be taken as limiting Applicant's right to claim disclosed, but not yet literally claimed subject matter by way of on or more further applications including those filed pursuant to 35 U.S.C. §120 and/or 35 U.S.C. §251.

1. A method for reducing micromasking residue remaining within an exposed interface region of an oxide-based hardmask layer and a metal-containing anti-reflection coating layer (ARC layer) after the hardmask layer has been patterned, where the residue includes nodules each having a base anchor portion and an upper body portion, the method comprising:
(a) providing a chemically reactive, first agent which will react with a first metal element of the metal-containing ARC layer to produce a volatile byproduct, the first agent being sufficiently small in size to operatively enter reaction zones of the base anchor portions of the residue nodules so as to react with the first metal element, if any, in the respective base anchor portions; and
(b) subjecting the residue nodules to a plasma including said chemically reactive, first agent.

2. The residue reducing method of claim 1 wherein
(a.1) said chemically reactive, first agent is selected from the group consisting of: chlorine and HCl.

3. The residue reducing method of claim 1 wherein
(a.1) said chemically reactive, first agent is selected from the group consisting of: Cl₂, HCl and BCl₃.

4. The residue reducing method of claim 1 wherein
(a.1) said first metal element is titanium.

5. The residue reducing method of claim 1 wherein
(a.1) said oxide-based hardmask layer includes Plasma-Enhanced Tetra-Ethyl-OrthoSilicate (PE-TEOS).

6. The residue reducing method of claim 5 wherein
(a.2) said interface region is defined by the PE-TEOS material contacting the metal-containing ARC layer.

7. The residue reducing method of claim 1 wherein
(b.1) in addition to said chemically reactive, first agent said subjecting step subjects the residue nodules and/or fibers to a plasma further including one or more additional chemically reactive agents which can react with, and volatize materials present in the base anchor portions of the residue nodules and/or fibers.

8. The residue reducing method of claim 1 and further comprising:
(c) providing a relatively, chemically nonreactive, second agent which does not substantially react with the first metal element of the metal-containing ARC layer to produce a volatile byproduct, the second agent being sufficiently large in average mass for physical bombardment purposes to operatively weaken attachments of the base anchor portions of the residue nodules to the interface region so as to thereby encourage break away and removal of the residue nodules from the interface region; and
(b.1) wherein in addition to said chemically reactive, first agent said subjecting step subjects the residue nodules and/or fibers to a plasma including said second agent.

9. The residue reducing method of claim 8 wherein
(a.1) said second agent is selected from the group consisting of: argon, helium, n on, krypton and nitrogen.

10. The residue reducing method of claim 8 wherein
(b.2) said subjecting step includes establishing a first inflow rate for the first agent in the range of about 10 sccm to about 50 sccm.

11. The residue reducing method of claim 10 wherein
(b.3) said subjecting step includes establishing a second inflow rate for the second agent in the range of about 50 sccm to about 150 sccm.

12. The residue reducing method of claim 11 wherein
(b.2a) said subjecting step includes establishing the first inflow rate for the first agent in the range of about 15 sccm to about 25 sccm; and
(b.3a) said subjecting step includes establishing the second inflow rate for the second agent in the range of about 70 sccm to about 90 sccm.

13. The residue reducing method of claim 11 wherein
(b.2b) said first agent is chlorine; and
(b.3b) said second agent is argon.

14. The residue reducing method of claim 8 wherein
(b.2) said subjecting step includes establishing a plasma pressure range of about 2 mT to about 15 mT.

15. The residue reducing method of claim 14 wherein
(b.2) said subjecting step includes establishing a plasma pressure range of about 6 mT to about 12 mT.

16. The residue reducing method of claim 8 wherein
(b.2) said subjecting step includes establishing a plasma power in the range of about 300 watts to about 600 watts.

17. The residue reducing method of claim 16 wherein
(b.2a) said subjecting step includes establishing for a chamber supporting said plasma, a pedestal bias power in the range of about 80 watts to about 200 watts.

18. The residue reducing method of claim 8 wherein
(b.2) said subjecting step includes maintaining said plasma having said first and second agents for an effective residue reducing time of about 3 seconds to about 20 seconds.

19. A computer-implementable recipe defined by one or both of computer-readable media and manufactured, computer instructing signals for use in a plasma chamber for reducing micromasking residue remaining within an interface region of an oxide-based hardmask layer and a metal-containing anti-reflection coating layer (ARC layer) after the hardmask layer has been patterned, where the residue includes nodules and/or fibers each having a base anchor portion and an upper body portion, the computer-implementable recipe being structured to cause the plasma chamber to carry out a residue reducing method comprising:
(a) providing into the chamber a chemically reactive, first agent which will react with a first metal element of the metal-containing ARC layer to produce a volatile byproduct, the first agent being sufficiently small in size to operatively enter reaction zones of the base anchor portions of the residue nodules and/or fibers so as to react with the first metal element, if any, in the respective base anchor portions of the residue nodules and/or fibers; and
(b) subjecting the residue nodules and/or fibers to an in-chamber plasma including said chemically reactive, first agent.

20. The computer-implementable recipe of claim 19 and further wherein said recipe-driven method of reducing residue is caused by the recipe to include:
(c) providing into the chamber a relatively, chemically nonreactive, second agent which does not substantially react with the first metal element of the metal-containing ARC layer to produce a volatile byproduct, the second agent being sufficiently large in mass for physical bombardment purposes to operatively weaken attachments of the base stems of the residue nodules and/or fibers to the interface region so as to thereby encourage break away and removal of the residue nodules and/or fibers from the interface region; and
(b.1) wherein in addition to said chemically reactive, first agent said subjecting step subjects the residue nodules and/or fibers to an in-chamber plasma including said second agent.

21. A patterned monolithic integrated circuit having a patterned metal layer whose pattern has been transferred through an interface region of an oxide-based hardmask layer and a metal-containing anti-reflection coating layer (ARC layer) where after the hardmask layer has been patterned, the interface region contains micromasking residue and the residue includes nodules and/or fibers each having a base anchor portion and an upper body portion, said monolithic integrated circuit being the product of a micromasking residue reducing method comprising:
(a) providing into a plasma chamber, a chemically reactive, first agent which will react with a first metal element of the metal-containing ARC layer to produce a volatile byproduct, the first agent being sufficiently small in size to operatively enter reaction zones of the base anchor portions of the residue nodules and/or fibers so as to react with the first metal element, if any, in the respective base anchor portions of the residue nodules and/or fibers;
(b) providing into the plasma chamber, a relatively, chemically nonreactive, second agent which does not substantially react with the first metal element of the metal-containing ARC layer to produce a volatile byproduct, the second agent being sufficiently large in mass for physical bombardment purposes to operatively weaken attachments of the base anchor portions of the residue nodules to the interface region so as to thereby encourage break away and removal of the residue nodules from the interface region; and
(c) subjecting the residue nodules and/or fibers to an in-chamber plasma including said first and second agents.

22. A patterned monolithic integrated circuit comprising:
(a) a patterned metal layer including a metal-containing anti-reflection coating layer (ARC layer);
(b) a patterned and oxide-based hardmask layer disposed on the ARC layer, where the pattern of the hardmask layer has be n used to pattern the underlying metal layer,
(b.1) where an interface region of the oxide-based hardmask layer and the metal-containing ARC layer contains buried nodules which would have constituted micromasking residue if the buried nodules had been exposed at the time the hardmask pattern was transferred to the metal layer.

23. The integrated circuit of claim 22 wherein the buried nodules include those having a base anchor portion rich in metal content from the metal-containing ARC layer, and an upper body portion that is resistant to removal by merely an oxide-etching process or merely a metal etching process.

24. A method for preventing or reducing formation of micromasking residue between a metal-containing anti-reflection coating layer (ARC layer) and an oxygen-containing hardmask layer where said residue can be microscopically observed after the hardmask layer has been patterned, said method of preventing or reducing comprising:
(a) interposing an oxygen-poor interfacial layer between the metal-containing ARC layer and the oxygen-containing hardmask layer.

25. The residue reducing method of claim 24 wherein:
(a.1) said ARC layer contains substantial amounts of titanium;
(a.2) said hardmask layer contains PE-TEOS; and
(a.3) said oxygen-poor interfacial layer is composed of SiₓO_{y}N_{z}, where x>0, z≧0 and where the density of oxygen in said oxygen-poor interfacial layer is less than the density of oxygen within the PE-TEOS of the adjacent layer hardmask layer.

26. The residue reducing method of claim 24 wherein:
(a.1a) the ratio of y to x is substantially less than 2 to 1.

27. The residue reducing method of claim 8 wherein a volumetric inflow ratio is established for respective inflow of the chemically reactive, first agent relative to inflow of the chemically nonreactive, second agent and said volumetric inflow ratio is in the range of about 1-to-10 (1:10) to about 4-to-10 (4:10).

28. The residue reducing method of claim 27 wherein said volumetric inflow ratio is in the range of about 2:10 to about 3:10.

29. The residue reducing method of claim 28 wherein said volumetric inflow ratio is about 1:4 (25%).

30. The residue reducing method of claim 29 wherein said chemically reactive, first agent includes chlorine and said chemically nonreactive, second agent includes argon.
